(19) United States
(12) Patent Application Publication
(10) Pub. No.: US 2024/0128291 A1
(43) Pub. Date: Apr. 18, 2024

(54) SENSOR PACKAGE STRUCTURE

(71) Applicant: TONG HSING ELECTRONIC INDUSTRIES, LTD., Taipei City (TW)

(72) Inventors: CHIA-SHUAI CHANG, Hsin-Chu County (TW); CHIEN-HUNG LIN, Taipei City (TW); WEI-LI WANG, Taipei City (TW); WEN-FU YU, Taipei City (TW); BAE-YINN HWANG, Taipei City (TW)

(21) Appl. No.: 18/206,146

(22) Filed: Jun. 6, 2023

Related U.S. Application Data
(60) Provisional application No. 63/416,721, filed on Oct. 17, 2022.

(30) Foreign Application Priority Data
Mar. 22, 2023 (TW) 112110586

(51) Int. Cl. H01L 27/146; H01L 23/00

(52) U.S. Cl. CPC H01L 27/14618; H01L 24/29; H01L 24/32; H01L 24/48; H01L 24/73; H01L 2224/29017; H01L 2224/32225; H01L 2224/48227; H01L 2224/73215

(57) ABSTRACT

A sensor package structure includes a substrate, a sensor chip disposed on and electrically coupled to the substrate, a light-permeable layer, an adhesive layer having a ring-shape and sandwiched between the sensor chip and the light-permeable layer, and an encapsulant formed on the substrate. The adhesive layer has two adhering surfaces having a same area and a middle cross section located at a middle position between the two adhering surfaces. An area of the middle cross section is 115% to 200% of an area of any one of the two adhering surfaces. The adhesive layer can provide for light to travel therethrough, and enables the light therein to change direction and to attenuate. The sensor chip, the adhesive layer, and the light-permeable layer are embedded in the encapsulant, and an outer surface of the light-permeable layer is at least partially exposed from the encapsulant.

### CROSS-REFERENCE TO RELATED PATENT APPLICATION

This application claims the benefit of priority to Taiwan Patent Application No. 112110586, filed on Mar. 22, 2023. The entire content of the above identified application is incorporated herein by reference.

This application claims the benefit of priority to the U.S. Provisional Patent Application Ser. No. 63/416,721 filed on Oct. 17, 2022, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

A conventional sensor package structure includes a light-permeable sheet, a sensor chip, and an adhesive layer that is adhered to and sandwiched between the light-permeable sheet and the sensor chip. However, light traveling onto the sensor chip by passing through the light-permeable sheet is easily reflected from the adhesive layer to affect a sensing region of the sensor chip (e.g., the sensing region may have a flare phenomenon).

### SUMMARY OF THE DISCLOSURE

In response to the above-referenced technical inadequacies, the present disclosure provides a sensor package structure to effectively improve on the issues associated with conventional sensor package structures.

In order to solve the above-mentioned problems, one of the technical aspects adopted by the present disclosure is to provide a sensor package structure, which includes a substrate, a sensor chip, an adhesive layer, a light-permeable layer, and an encapsulant. The sensor chip is disposed on the substrate along a predetermined direction and is electrically coupled to the substrate. Moreover, a top surface of the sensor chip has a sensing region and a carrying region that surrounds the sensing region. The adhesive layer has an annular shape and is disposed on the carrying region of the sensor chip. The adhesive layer has a bottom adhering surface, a top adhering surface, and a middle cross section. The bottom adhering surface is connected to the carrying region. The top adhering surface is parallel to the bottom adhering surface. An area of the top adhering surface is equal to an area of the bottom adhering surface, and the top adhering surface and the bottom adhering surface are entirely overlapped with each other along the predetermined direction. The middle cross section is parallel to the bottom adhering surface. Any one of the top adhering surface and the bottom adhering surface is spaced apart from the middle cross section along the predetermined direction by a same distance, and an area of the middle cross section is 110% to 150% of the area of the bottom adhering surface. The adhesive layer is configured to allow light to pass therethrough and is configured to enable the light to change a traveling direction therein and to have an attenuation therein. The light-permeable layer has an outer surface and an inner surface that is opposite to the outer surface. The light-permeable layer is disposed on the top adhering surface of the adhesive layer, so that the light-permeable layer, the adhesive layer, and the sensor chip jointly define an enclosed space. The encapsulant is formed on the substrate. The sensor chip, the adhesive layer, and the light-permeable layer are embedded in the encapsulant, and the outer surface of the light-permeable layer is at least partially exposed from the encapsulant.

In order to solve the above-mentioned problems, another one of the technical aspects adopted by the present disclosure is to provide a sensor package structure, which includes a substrate, a sensor chip, an adhesive layer, a light-permeable layer, and an encapsulant. The sensor chip is disposed on the substrate along a predetermined direction and is electrically coupled to the substrate. A top surface of the sensor chip has a sensing region and a carrying region that surrounds the sensing region. The adhesive layer has an annular shape and is disposed on the carrying region of the sensor chip. The adhesive layer has a bottom adhering surface, a top adhering surface, and a middle cross section. The bottom adhering surface is connected to the carrying region. The top adhering surface is parallel to the bottom adhering surface. An area of the top adhering surface is equal to an area of the bottom adhering surface, and the top adhering surface and the bottom adhering surface are entirely overlapped with each other along the predetermined direction. The middle cross section is parallel to the bottom adhering surface. Any one of the top adhering surface and the bottom adhering surface is spaced apart from the middle cross section along the predetermined direction by a same distance, an area of the middle cross section is 90% to 110% of the area of the bottom adhering surface, and the bottom adhering surface and the middle cross section are partially overlapped with each other along the predetermined direction. The adhesive layer is configured to allow light to pass therethrough and is configured to enable the light to change a traveling direction therein and to have an attenuation therein. The light-permeable layer has an outer surface and an inner surface that is opposite to the outer surface. The light-permeable layer is disposed on the top adhering surface of the adhesive layer, so that the light-permeable layer, the adhesive layer, and the sensor chip jointly define an enclosed space. The encapsulant is formed on the substrate. The sensor chip, the adhesive layer, and the light-permeable layer are embedded in the encapsulant, and the outer surface of the light-permeable layer is at least partially exposed from the encapsulant.

In order to solve the above-mentioned problems, yet another one of the technical aspects adopted by the present disclosure is to provide a sensor package structure, which includes a substrate, a sensor chip, an adhesive layer, a light-permeable layer, and an encapsulant. The sensor chip is disposed on the substrate along a predetermined direction and is electrically coupled to the substrate. A top surface of the sensor chip has a sensing region and a carrying region that surrounds the sensing region. The adhesive layer has an annular shape and is disposed on the carrying region of the sensor chip. The adhesive layer has a bottom adhering surface, a top adhering surface, and a middle cross section. The bottom adhering surface is connected to the carrying region. The top adhering surface is parallel to the bottom adhering surface. An area of the top adhering surface is equal to an area of the bottom adhering surface, and the top adhering surface and the bottom adhering surface are partially overlapped with each other along the predetermined direction. The middle cross section is parallel to the bottom adhering surface. Any one of the top adhering surface and the bottom adhering surface is spaced apart from the middle cross section along the predetermined direction by a same distance. The adhesive layer is configured to allow light to pass therethrough and is configured to enable the light to change a traveling direction therein and to have an attenuation therein. The light-permeable layer has an outer surface and an inner surface that is opposite to the outer surface. The light-permeable layer is disposed on the top adhering surface of the adhesive layer, so that the light-permeable layer, the adhesive layer, and the sensor chip jointly define an enclosed space. The encapsulant is formed on the substrate. The sensor chip, the adhesive layer, and the light-permeable layer are embedded in the encapsulant, and the outer surface of the light-permeable layer is at least partially exposed from the encapsulant.

Therefore, the adhesive layer of the sensor package structure provided by the present disclosure is formed by having the middle cross section be in structural cooperation with the bottom adhering surface and the top adhering surface, so that the structure of the adhesive layer is suitable for enabling the light traveling therein to change direction and to attenuate, thereby effectively reducing the flare phenomenon generated in the sensor package structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic top view of FIG. 1;

FIG. 3 is a schematic cross-sectional view taken along line III-III of FIG. 2;

FIG. 4 is an enlarged view of part IV of FIG. 3;

FIG. 5 is a schematic cross-sectional view of the sensor package structure in another configuration according to the first embodiment of the pre sent disclosure;

FIG. 6 is a schematic cross-sectional view of the sensor package structure in yet another configuration according to the first embodiment of the pre sent disclosure;

FIG. 7 is a schematic cross-sectional view of the sensor package structure according to a second embodiment of the present disclosure;

FIG. 8 is a schematic cross-sectional view of the sensor package structure in another configuration according to the second embodiment of the pre sent disclosure;

FIG. 9 is a schematic cross-sectional view of the sensor package structure according to a third embodiment of the present disclosure;

FIG. 10 is an enlarged view of part X of FIG. 9;

FIG. 11 is a schematic cross-sectional view of the sensor package structure in yet another configuration according to the third embodiment of the pre sent disclosure;

FIG. 12 is a schematic cross-sectional view of the sensor package structure in still yet another configuration according to the third embodiment of the present disclosure;

FIG. 13 is a schematic cross-sectional view of the sensor package structure according to a fourth embodiment of the present disclosure;

FIG. 14 is a schematic cross-sectional view of the sensor package structure in yet another configuration according to the fourth embodiment of the present disclosure; and

FIG. 15 is a schematic cross-sectional view of the sensor package structure in still yet another configuration according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

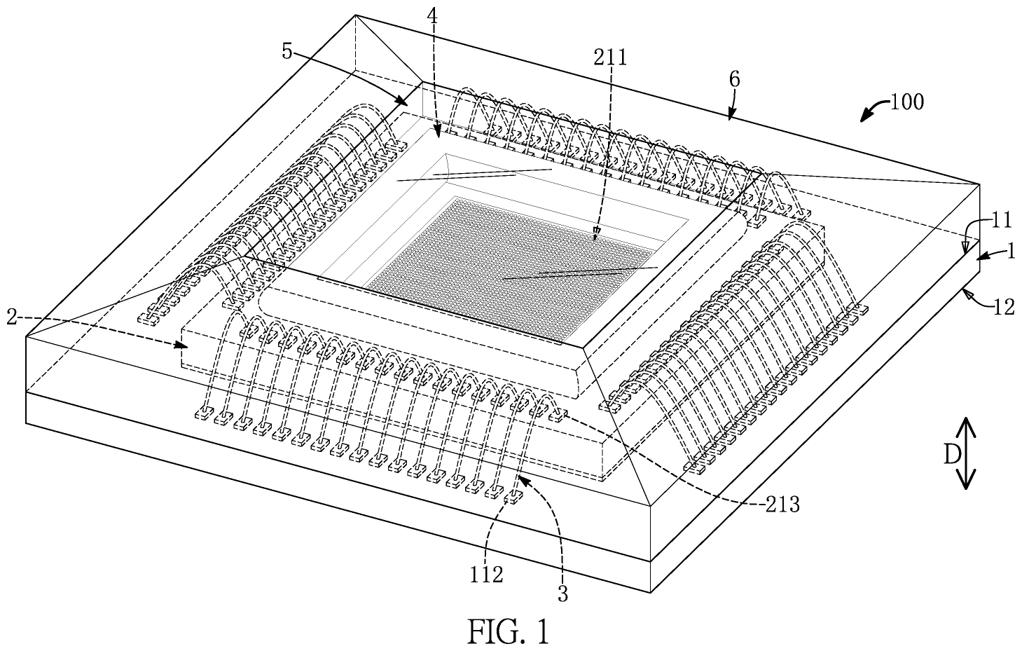

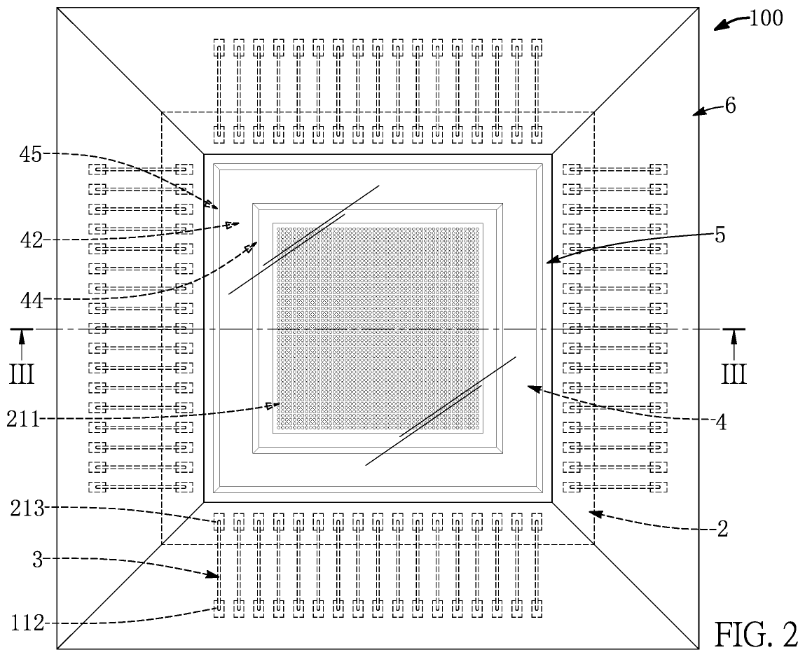

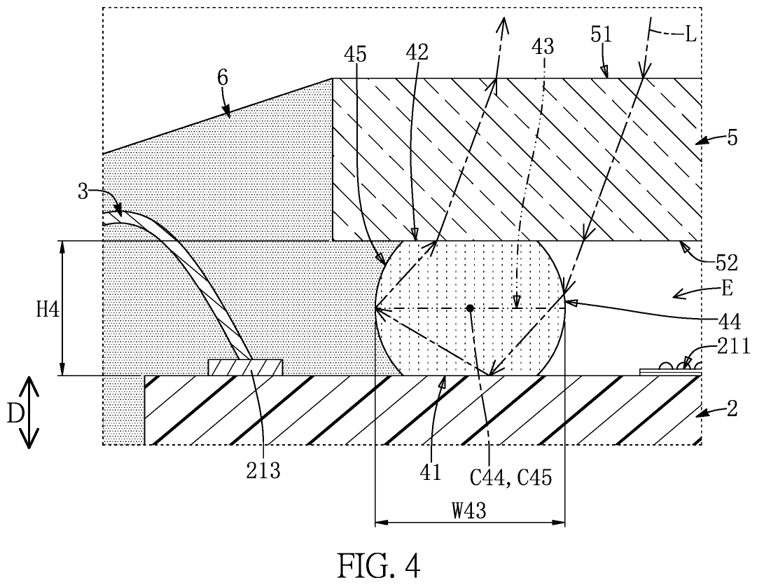

Referring to FIG. 1 to FIG. 6, a first embodiment of the present disclosure is provided. As shown in FIG. 1 and FIG. 2, the present embodiment provides a sensor package structure 100. In other words, any package structure not encapsulating a sensor chip therein has a structural design different from that of the sensor package structure 100 of the present embodiment.

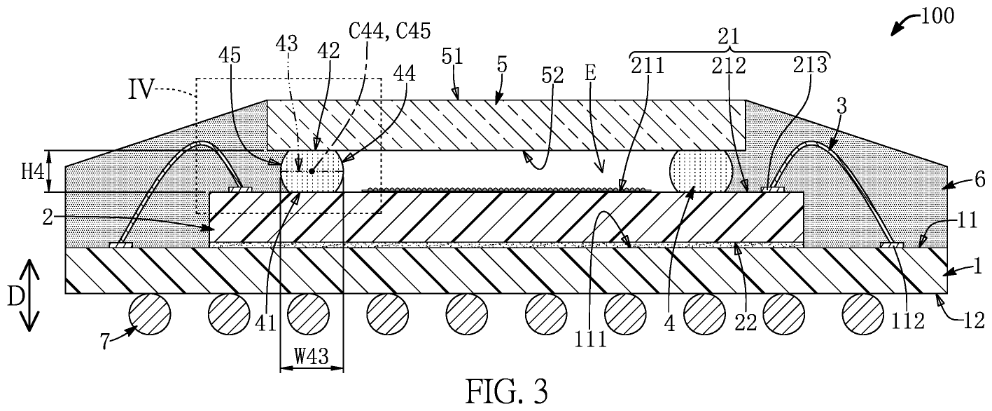

As shown in FIG. 3 to FIG. 6, the sensor package structure 100 includes a substrate 1, a sensor chip 2 disposed on the substrate 1, a plurality of metal wires 3 electrically coupled to the sensor chip 2 and the substrate 1, an adhesive layer 4 having a ring shape and being disposed on the sensor chip 2, a light-permeable layer 5 disposed on the adhesive layer 4, and an encapsulant 6 that is formed on the substrate 1.

The sensor package structure 100 in the present embodiment includes the above components, but can be adjusted or changed according to design requirements. For example, in other embodiments of the present disclosure not shown in the drawings, the sensor package structure 100 can be provided without the metal wires 3, and the sensor chip 2 is fixed onto and electrically coupled to the substrate 1 in a flip-chip manner or an adhering manner. The structure and connection relationship of each component of the sensor package structure 100 will be recited in the following description.

The substrate 1 of the present embodiment has a square shape or a rectangular shape, but the present disclosure is not limited thereto. An upper surface 11 of the substrate 1 includes a chip-bonding region 111 arranged approximately on a center portion thereof, and the substrate 1 includes a plurality of bonding pads 112 that are disposed on the upper surface 11 and are arranged outside of the chip-bonding region 111. The bonding pads 112 in the present embodiment are in a ring-shaped arrangement, but the present disclosure is not limited thereto. For example, in other embodiments of the present disclosure not shown in the drawings, the bonding pads 112 can be arranged in two rows respectively at two opposite sides of the chip-bonding region 111.

In addition, the substrate 1 can be further provided with a plurality of solder balls 7 disposed on a lower surface 12 thereof. The substrate 1 can be soldered onto an electronic component (not shown in the drawings) through the solder balls 7, thereby electrically connecting the sensor package structure 100 to the electronic component.

The sensor chip 2 in the present embodiment has a square shape or a rectangular shape and is an image sensor chip, but the present disclosure is not limited thereto. A bottom surface 22 of the sensor chip 2 is fixed onto the chip-bonding region 111 of the substrate 1 (through a chip-bonding adhesive) along a predetermined direction D. In other words, the sensor chip 2 is arranged to be surrounded on the inside of the bonding pads 112. Moreover, a top surface 21 of the sensor chip 2 has a sensing region 211 and a carrying region 212 that has a ring shape arranged around (or surrounding) the sensing region 211. Two ends of each of the metal wires 3 are respectively connected to the substrate 1 and the carrying region 212 of the sensor chip 2, so that the substrate 1 and the sensor chip 2 are electrically coupled to each other.

Specifically, the sensor chip 2 includes a plurality of connection pads 213 arranged on the carrying region 212. In other words, the connection pads 213 are arranged outside of the sensing region 211. The number and positions of the connection pads 213 of the sensor chip 2 in the present embodiment correspond to those of the bonding pads 112 of the substrate 1. In other words, the connection pads 213 in the present embodiment are substantially in a ring-shaped arrangement. Moreover, the two ends of each of the metal wires 3 are respectively connected to one of the bonding pads 112 and the corresponding connection pad 213.

The adhesive layer 4 is disposed on the carrying region 212 of the sensor chip 2 and surrounds the sensing region 211, and each of the metal wires 3 is located outside of the adhesive layer 4. The adhesive layer 4 has a bottom adhering surface 41 connected to the carrying region 212, a top adhering surface 42 connected to the light-permeable layer 5, and a middle cross section 43 that is arranged between the bottom adhering surface 41 and the top adhering surface 42.

It should be noted that the adhesive layer 4 is configured to allow light L to pass therethrough and is configured to enable the light L to change a traveling direction therein and to have an attenuation therein, thereby effectively reducing the flare phenomenon generated in the sensor package structure 100. In the present embodiment, the adhesive layer 4 is formed by having the middle cross section 43 be in structural cooperation with the bottom adhering surface 41 and the top adhering surface 42, so that the structure of the adhesive layer 4 is suitable to enable the light L to change the traveling direction therein and to have the attenuation therein.

Specifically, the bottom adhering surface 41, the top adhering surface 42, and the middle cross section 43 are parallel to each other and are perpendicular to the predetermined direction D. Any one of the top adhering surface 42 and the bottom adhering surface 41 is spaced apart from the middle cross section 43 along the predetermined direction D by a same distance. An area of the top adhering surface 42 is equal to an area of the bottom adhering surface 41, and the top adhering surface 42 and the bottom adhering surface 41 are entirely overlapped with each other along the predetermined direction D. In other words, a contour of the bottom adhering surface 41 is flush with a contour of the top adhering surface 42 along the predetermined direction D; or, a projection region defined by orthogonally projecting the top adhering surface 42 onto the top surface 21 along the predetermined direction D is entirely overlapped with the bottom adhering surface 41.

Moreover, an area of the middle cross section 43 is 110% to 150% of the area of the bottom adhering surface 41. Specifically, out of all the cross sections of the adhesive layer 4 perpendicular to the predetermined direction D, any one of the area of the bottom adhering surface 41 and the area of the top adhering surface 42 is a smallest area, and the area of the middle cross section 43 is largest. In other words, the adhesive layer 4 has a wide center segment and two narrow end segments.

In addition, the adhesive layer 4 has an inner side 44 arranged adjacent to the sensing region 211 and an outer side 45 that is arranged adjacent to the connection pads 213. Specific shapes of the inner side 44 and the outer side 45 of the adhesive layer 4 can be adjusted or changed according to design requirements, so that all possible shapes of the inner side 44 and the outer side 45 cannot be shown in the drawings of the present embodiment, and the following description only discusses some preferable shapes of the inner side 44 and the outer side 45, but the present disclosure is not limited thereto.

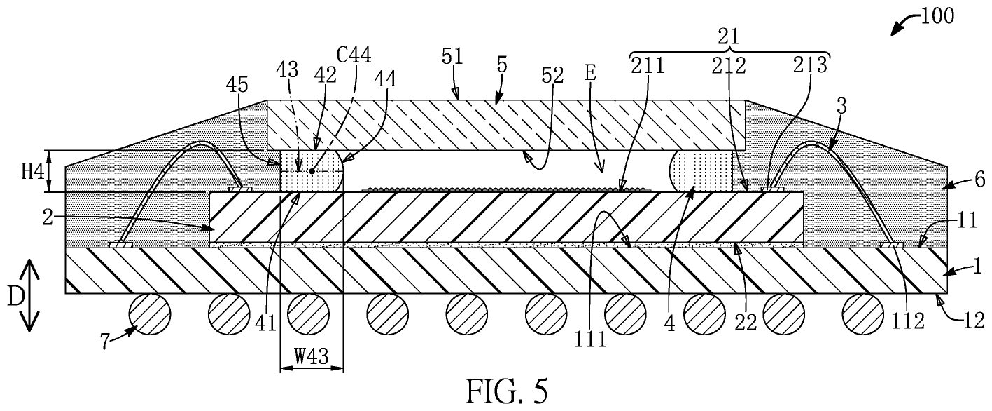

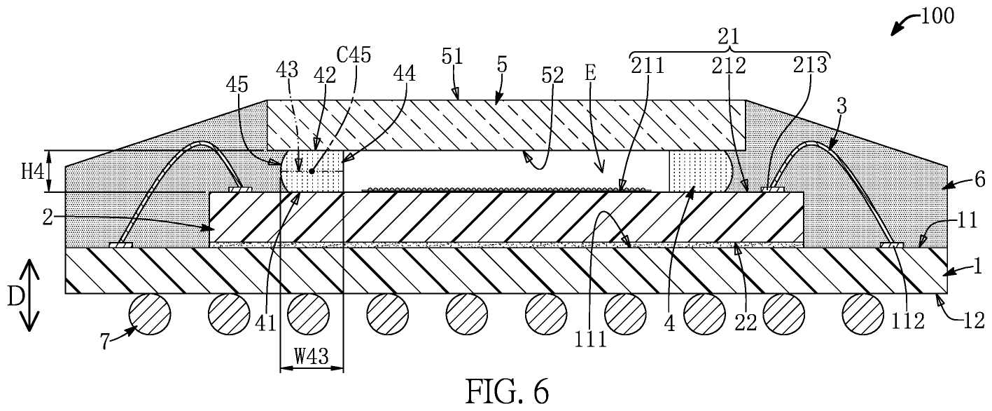

At least one of the inner side 44 and the outer side 45 is a curved surface, and any one of the inner side 44 and the outer side 45 of the adhesive layer 4 does not have a concave surface. For example, as shown in FIG. 3, each of the inner side 44 and the outer side 45 can be a convex surface; or, as shown in FIG. 5 and FIG. 6, one of the inner side 44 and the outer side 45 can be a convex surface.

Specifically, in a cross-sectional view of the adhesive layer 4 perpendicular to the middle cross section 43, at least one of the inner side 44 and the outer side 45 is in a circular arc shape having a center of circle C44, C45 that is located on the middle cross section 43, and a width W43 of the middle cross section 43 is 10% to 500% of a distance H4 between the bottom adhering surface 41 and the top adhering surface 42.

The light-permeable layer 5 in the present embodiment is a transparent and flat glass board, but the present disclosure is not limited thereto. The light-permeable layer 5 has an outer surface 51 and an inner surface 52 that is opposite to the outer surface 51. The light-permeable layer 5 (e.g., the inner surface 52) is disposed on the top adhering surface 42 of the adhesive layer 4, so that the light-permeable layer 5, the adhesive layer 4, and the sensor chip 2 jointly define an enclosed space E. The inner side 44 of the adhesive layer 4 and the sensing region 211 of the sensor chip 2 are arranged in the enclosed space E.

The encapsulant 6 of the present embodiment is opaque for blocking a visible light from passing therethrough. The encapsulant 6 is a liquid encapsulation and is formed on the upper surface 11 of the substrate 1, and edges of the encapsulant 6 are flush with edges of the substrate 1. The sensor chip 2, the adhesive layer 4, the light-permeable layer 5, and each of the metal wires 3 are embedded in the encapsulant 6 (e.g., the outer side 45 of the adhesive layer 4 is connected to the encapsulant 6), and at least part of the outer surface 51 of the light-permeable layer 5 is exposed from the encapsulant 6, but the present disclosure is not limited thereto.

It should be noted that the conventional sensor package structure is often provided to improve the flare phenomenon by changing an inner side of adhesive layer (e.g., the inner side of the adhesive layer having a sawtooth shape) to scatter light. However, the sensor package structure 100 of the present embodiment breaks away from the established prejudice of the above-mentioned related art by providing the overall structure of the adhesive layer 4 that enables the light L to change the traveling direction therein and to have the attenuation therein, thereby effectively reducing the flare phenomenon generated in the sensor package structure 100.

### Second Embodiment

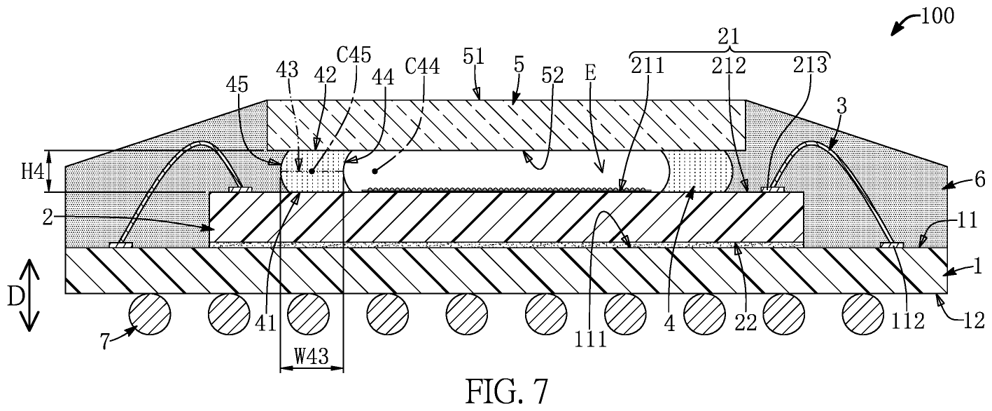

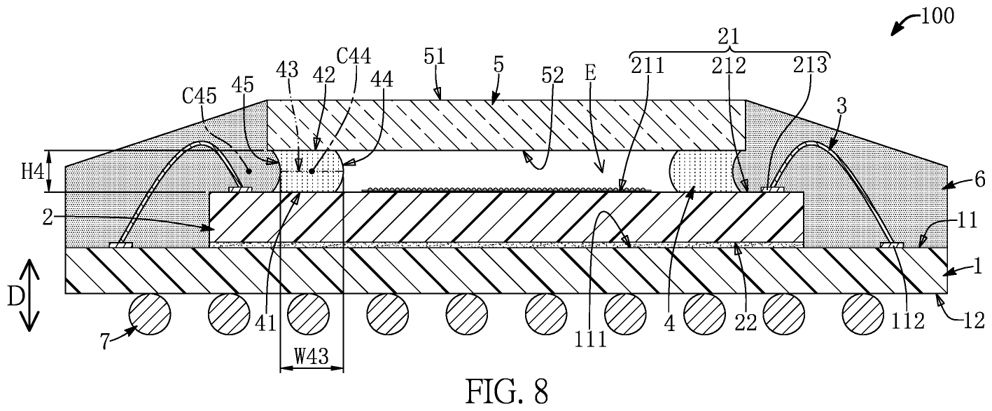

Referring to FIG. 7 and FIG. 8, a second embodiment of the present disclosure, which is similar to the first embodiment of the present disclosure, is provided. For the sake of brevity, descriptions of the same components in the first and second embodiments of the present disclosure (e.g., the substrate 1, the sensor chip 2, the metal wires 3, the light-permeable layer 5, and the encapsulant 6) will be omitted herein, and the main difference between the second embodiment and the first embodiment is a specific structure of the adhesive layer 4.

In the present embodiment, the adhesive layer 4 has a bottom adhering surface 41 connected to the carrying region 212, a top adhering surface 42 connected to the light-permeable layer 5, and a middle cross section 43 that is arranged between the bottom adhering surface 41 and the top adhering surface 42.

It should be noted that the adhesive layer 4 is configured to allow light L to pass therethrough and is configured to enable the light L to change a traveling direction therein and to have an attenuation therein, thereby effectively reducing the flare phenomenon generated in the sensor package structure 100. In the present embodiment, the adhesive layer 4 is formed by having the middle cross section 43 be in structural cooperation with the bottom adhering surface 41 and the top adhering surface 42, so that the structure of the adhesive layer 4 is suitable to enable the light L to change the traveling direction therein and to have the attenuation therein.

Specifically, the bottom adhering surface 41, the top adhering surface 42, and the middle cross section 43 are parallel to each other and are perpendicular to the predetermined direction D. Any one of the top adhering surface 42 and the bottom adhering surface 41 is spaced apart from the middle cross section 43 along the predetermined direction D by a same distance. An area of the top adhering surface 42 is equal to an area of the bottom adhering surface 41, and the top adhering surface 42 and the bottom adhering surface 41 are entirely overlapped with each other along the predetermined direction D. In other words, a contour of the bottom adhering surface 41 is flush with a contour of the top adhering surface 42 along the predetermined direction D.

Moreover, an area of the middle cross section 43 is 90% to 110% of the area of the bottom adhering surface 41, and the bottom adhering surface 41 and the middle cross section 43 are (only) partially overlapped with each other along the predetermined direction D. In the present embodiment, all cross sections of the adhesive layer 4 perpendicular to the predetermined direction D preferably have a same area (e.g., the area of the middle cross section 43 is equal to the area of the bottom adhering surface 41), and the middle cross section 43 is staggeredly arranged relative to any one of the bottom adhering surface 41 and the top adhering surface 42.

In addition, the adhesive layer 4 has an inner side 44 arranged in the enclosed space E and an outer side 45 that is connected to the encapsulant 6. Specific shapes of the inner side 44 and the outer side 45 of the adhesive layer 4 can be adjusted or changed according to design requirements, so that all possible shapes of the inner side 44 and the outer side 45 cannot be shown in the drawings of the present embodiment, and the following description only discusses some preferable shapes of the inner side 44 and the outer side 45, but the present disclosure is not limited thereto.

One of the inner side 44 and the outer side 45 is a concave surface, and another one of the inner side 44 and the outer side 45 is a convex surface. Specifically, in a cross-sectional view of the adhesive layer 4 perpendicular to the middle cross section 43, any one of the convex surface and the concave surface is preferably in a circular arc shape and has a same radius, the convex surface has a center of circle C44, C45 located on the middle cross section 43, the concave surface has a center of circle C44, C45 located on a virtual plane extending from the middle cross section 43, and a width W43 of the middle cross section 43 is 10% to 500% of a distance H4 between the bottom adhering surface 41 and the top adhering surface 42.

### Third Embodiment

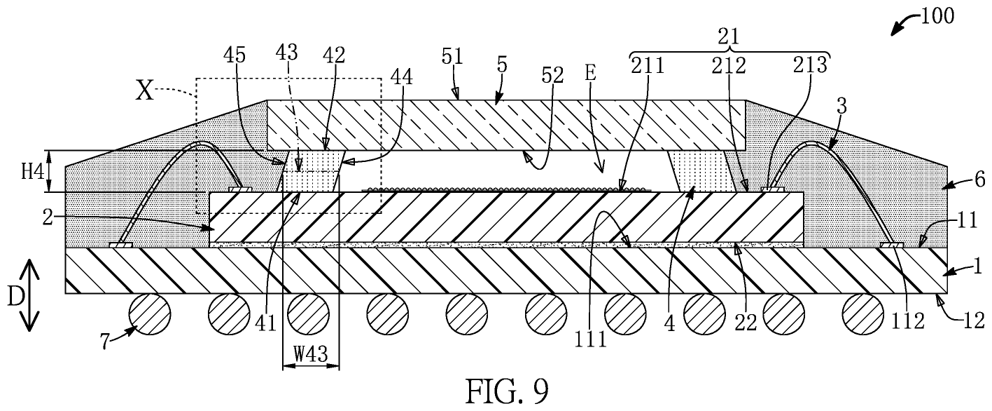

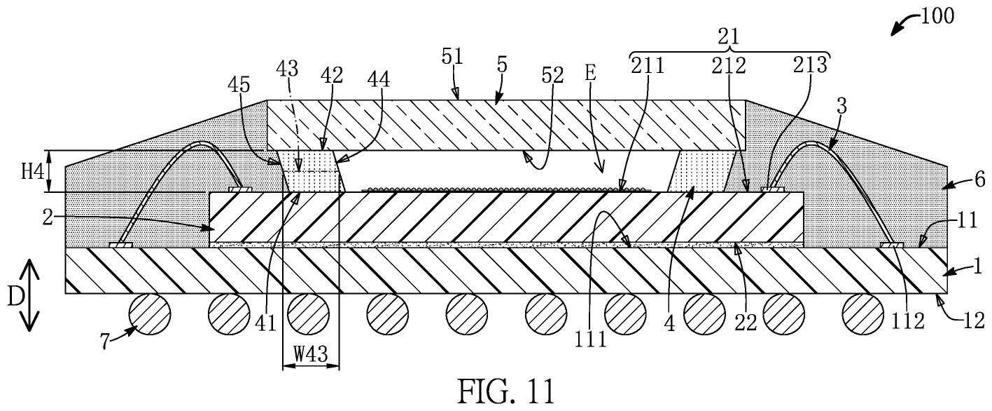

Referring to FIG. 9 to FIG. 12, a third embodiment of the present disclosure, which is similar to the first embodiment of the present disclosure, is provided. For the sake of brevity, descriptions of the same components in the first and third embodiments of the present disclosure (e.g., the substrate 1, the sensor chip 2, the metal wires 3, the light-permeable layer 5, and the encapsulant 6) will be omitted herein, and the main difference between the third embodiment and the first embodiment is a specific structure of the adhesive layer 4.

In the present embodiment, as shown in FIG. 9 to FIG. 11, the adhesive layer 4 has a bottom adhering surface 41 connected to the carrying region 212, a top adhering surface 42 connected to the light-permeable layer 5, and a middle cross section 43 that is arranged between the bottom adhering surface 41 and the top adhering surface 42.

It should be noted that the adhesive layer 4 is configured to allow light L to pass therethrough and is configured to enable the light L to change a traveling direction therein and to have an attenuation therein, thereby effectively reducing the flare phenomenon generated in the sensor package structure 100. In the present embodiment, the adhesive layer 4 is formed by having the middle cross section 43 be in structural cooperation with the bottom adhering surface 41 and the top adhering surface 42, so that the structure of the adhesive layer 4 is suitable to enable the light L to change the traveling direction therein and to have the attenuation therein.

Specifically, the bottom adhering surface 41, the top adhering surface 42, and the middle cross section 43 are parallel to each other and are perpendicular to the predetermined direction D. Any one of the top adhering surface 42 and the bottom adhering surface 41 is spaced apart from the middle cross section 43 along the predetermined direction D by a same distance. An area of the top adhering surface 42 is equal to an area of the bottom adhering surface 41, and the top adhering surface 42 and the bottom adhering surface 41 are (only) partially overlapped with each other along the predetermined direction D. In other words, the bottom adhering surface 41 is staggeredly arranged relative to the top adhering surface 42, and the top adhering surface 42 is not located directly above the sensing region 211.

Moreover, an area of the middle cross section 43 is 90% to 110% of the area of the bottom adhering surface 41, and the bottom adhering surface 41 and the middle cross section 43 are (only) partially overlapped with each other along the predetermined direction D. In the present embodiment, all cross sections of the adhesive layer 4 perpendicular to the predetermined direction D preferably have a same area (e.g., the area of the middle cross section 43 is equal to the area of the bottom adhering surface 41), and the middle cross section 43 is staggeredly arranged relative to any one of the bottom adhering surface 41 and the top adhering surface 42.

In addition, the adhesive layer 4 has an inner side 44 arranged in the enclosed space E and an outer side 45 that is connected to the encapsulant 6. Specific shapes of the inner side 44 and the outer side 45 of the adhesive layer 4 can be adjusted or changed according to design requirements, so that all possible shapes of the inner side 44 and the outer side 45 cannot be shown in the drawings of the present embodiment, and the following description only discusses some preferable shapes of the inner side 44 and the outer side 45, but the present disclosure is not limited thereto.

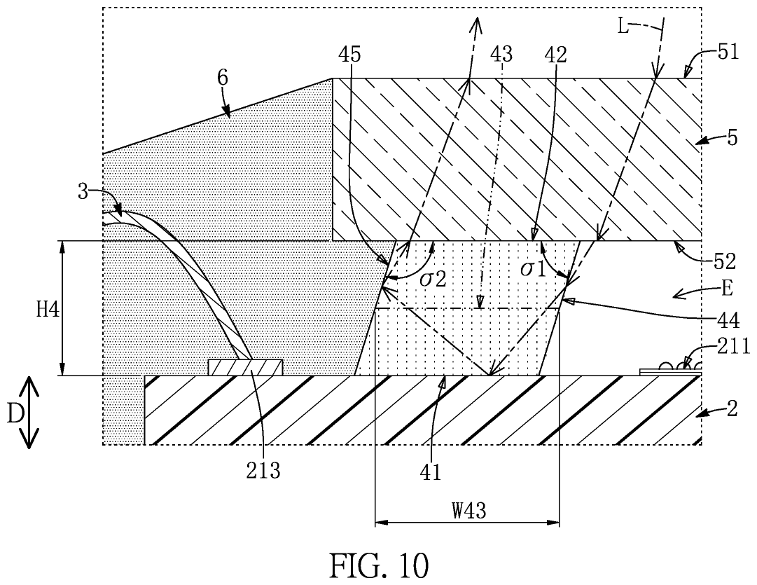

As shown in FIG. 10, in a cross-sectional view of the adhesive layer 4 perpendicular to the middle cross section 43, a width W43 of the middle cross section 43 is 10% to 500% of a distance H4 between the bottom adhering surface 41 and the top adhering surface 42, and the bottom adhering surface 41, the top adhering surface 42, the inner side 44, and the outer side 45 jointly form a parallelogram having two obtuse angles 61 and two acute angles 62, where any one of the two acute angles 62 is within a range from 10 degrees to 80 degrees, but the present disclosure is not limited thereto.

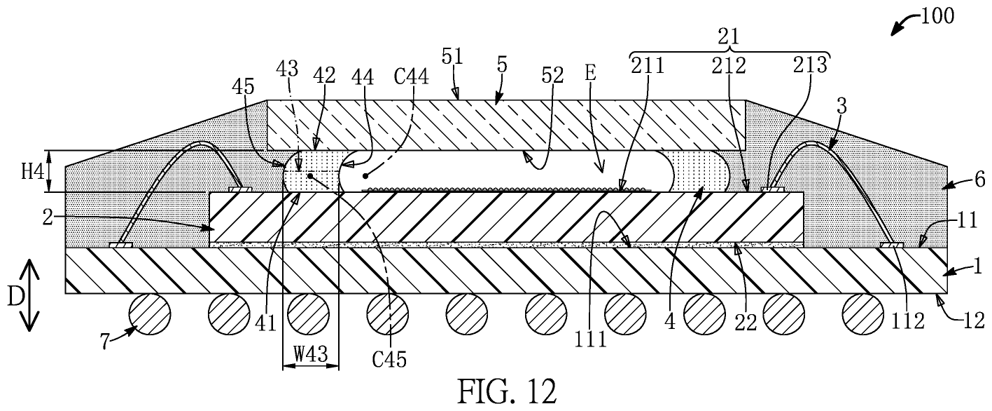

As shown in FIG. 12, one of the inner side 44 and the outer side 45 is a concave surface, and another one of the inner side 44 and the outer side 45 is a convex surface. Moreover, any one of the convex surface and the concave surface is preferably in a circular arc shape, the convex surface and the concave surface have a same radius, and the convex surface has a center of circle C45 that is located in the adhesive layer 4 and that is not located on the middle cross section 43.

### Fourth Embodiment

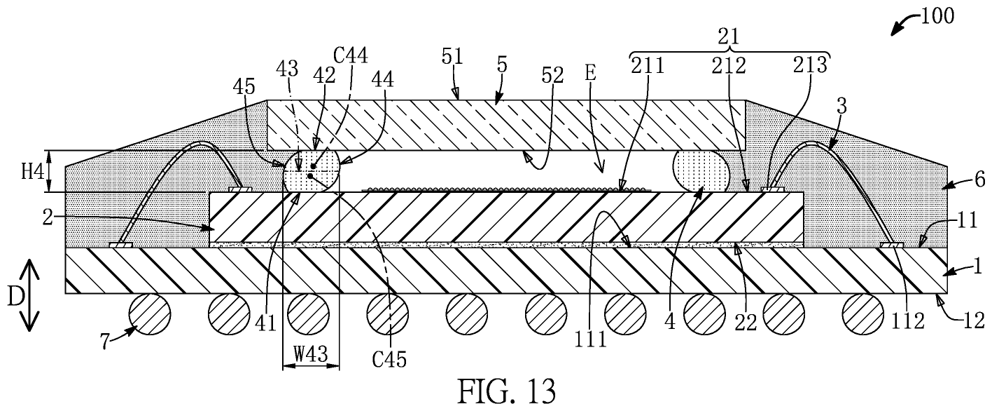

Referring to FIG. 13 to FIG. 15, a fourth embodiment of the present disclosure, which is similar to the third embodiment of the present disclosure, is provided. For the sake of brevity, descriptions of the same components in the third and fourth embodiments of the present disclosure (e.g., the substrate 1, the sensor chip 2, the metal wires 3, the light-permeable layer 5, and the encapsulant 6) will be omitted herein, and the main difference between the fourth embodiment and the third embodiment is a specific structure of the adhesive layer 4.

In the present embodiment, an area of the middle cross section 43 is 110% to 150% of the area of the bottom adhering surface 41. Specifically, out of all the cross sections of the adhesive layer 4 perpendicular to the predetermined direction D, any one of the area of the bottom adhering surface 41 and the area of the top adhering surface 42 is minimal, and the area of the middle cross section 43 is largest. In other words, the adhesive layer 4 has a wide center segment and two narrow end segments.

In addition, the adhesive layer 4 has an inner side 44 arranged adjacent to the sensing region 211 and an outer side 45 that is arranged adjacent to the connection pads 213. Specific shapes of the inner side 44 and the outer side 45 of the adhesive layer 4 can be adjusted or changed according to design requirements, so that all possible shapes of the inner side 44 and the outer side 45 cannot be shown in the drawings of the present embodiment, and the following description only discusses some preferable shapes of the inner side 44 and the outer side 45, but the present disclosure is not limited thereto.

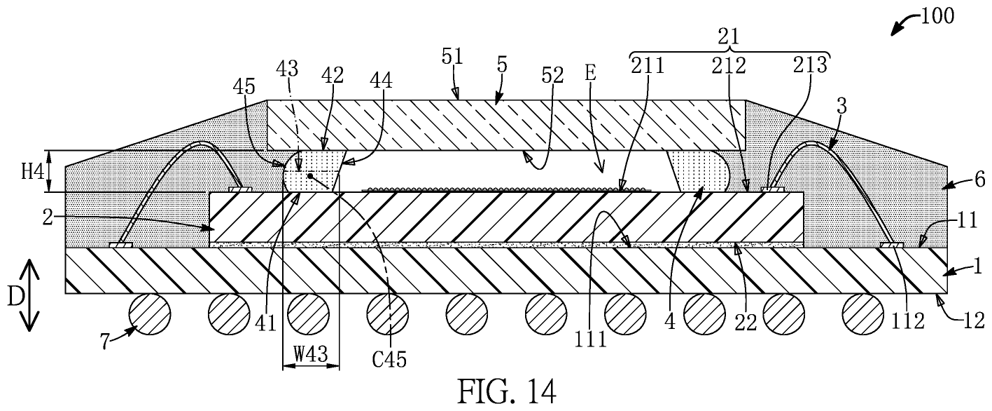

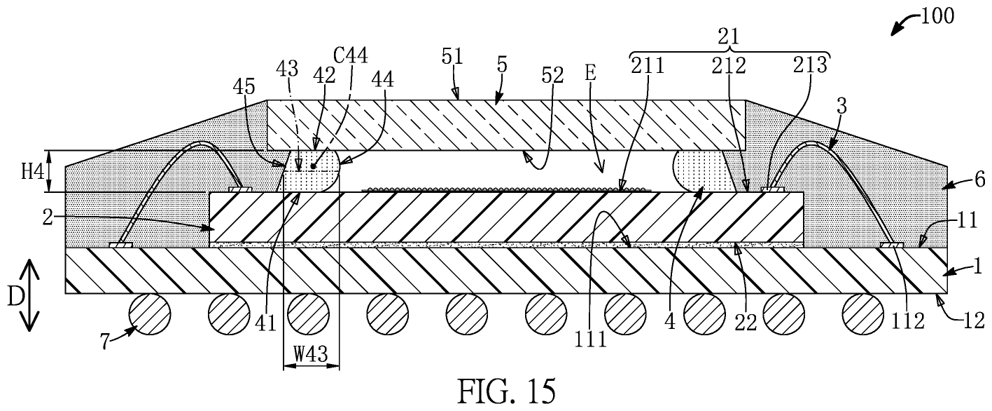

At least one of the inner side 44 and the outer side 45 is a curved surface, and any one of the inner side 44 and the outer side 45 of the adhesive layer 4 does not have a concave surface. For example, as shown in FIG. 13, each of the inner side 44 and the outer side 45 can be a convex surface; or, as shown in FIG. 14 and FIG. 15, one of the inner side 44 and the outer side 45 can be a convex surface.

Specifically, in a cross-sectional view of the adhesive layer 4 perpendicular to the middle cross section 43, at least one of the inner side 44 and the outer side 45 is in a circular arc shape having a center of circle C44, C45 that is located in the adhesive layer 4 and that is not located on the middle cross section 43, and a width W43 of the middle cross section 43 is 10% to 500% of a distance H4 between the bottom adhering surface 41 and the top adhering surface 42.

### Beneficial Effects of the Embodiments

In conclusion, the adhesive layer of the sensor package structure provided by the present disclosure is formed by having the middle cross section be in structural cooperation with the bottom adhering surface and the top adhering surface, so that the structure of the adhesive layer is suitable for enabling the light traveling therein to change direction and to attenuate, thereby effectively reducing the flare phenomenon generated in the sensor package structure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate;
a sensor chip disposed on the substrate along a predetermined direction and electrically coupled to the substrate, wherein a top surface of the sensor chip has a sensing region and a carrying region that surrounds the sensing region;
an adhesive layer having an annular shape and being disposed on the carrying region of the sensor chip, wherein the adhesive layer has:
a bottom adhering surface connected to the carrying region;
a top adhering surface parallel to the bottom adhering surface, wherein an area of the top adhering surface is equal to an area of the bottom adhering surface, and the top adhering surface and the bottom adhering surface are entirely overlapped with each other along the predetermined direction; and
a middle cross section parallel to the bottom adhering surface, wherein any one of the top adhering surface and the bottom adhering surface is spaced apart from the middle cross section along the predetermined direction by a same distance, and an area of the middle cross section is 110% to 150% of the area of the bottom adhering surface;
wherein the adhesive layer is configured to allow light to pass therethrough and is configured to enable the light to change a traveling direction therein and to have an attenuation therein;
a light-permeable layer having an outer surface and an inner surface that is opposite to the outer surface, wherein the light-permeable layer is disposed on the top adhering surface of the adhesive layer, so that the light-permeable layer, the adhesive layer, and the sensor chip jointly define an enclosed space; and
an encapsulant formed on the substrate, wherein the sensor chip, the adhesive layer, and the light-permeable layer are embedded in the encapsulant, and the outer surface of the light-permeable layer is at least partially exposed from the encapsulant.

2. The sensor package structure according to claim 1, wherein the adhesive layer has an inner side arranged in the enclosed space and an outer side that is connected to the encapsulant, and at least one of the inner side and the outer side is a curved surface.

3. The sensor package structure according to claim 2, wherein any one of the inner side and the outer side of the adhesive layer does not have a concave surface.

4. The sensor package structure according to claim 1, wherein the adhesive layer has an inner side arranged in the enclosed space and an outer side that is connected to the encapsulant, and wherein, in a cross-sectional view of the adhesive layer perpendicular to the middle cross section, at least one of the inner side and the outer side has a circular arc shape having a center of circle located on the middle cross section.

5. The sensor package structure according to claim 1, wherein the middle cross section is perpendicular to the predetermined direction, and wherein, out of all cross sections of the adhesive layer perpendicular to the predetermined direction, the area of the middle cross section is largest.

6. The sensor package structure according to claim 5, wherein, out of all the cross sections of the adhesive layer perpendicular to the predetermined direction, any one of the area of the bottom adhering surface and the area of the top adhering surface is smallest.

7. The sensor package structure according to claim 1, further comprising a plurality of metal wires, wherein two ends of any one of the metal wires are respectively connected to the substrate and the carrying region of the sensor chip, so that the substrate and the sensor chip are electrically coupled to each other, and wherein each of the metal wires is located outside of the adhesive layer and is embedded in the encapsulant.

8. A sensor package structure, comprising:
a substrate;
a sensor chip disposed on the substrate along a predetermined direction and electrically coupled to the substrate, wherein a top surface of the sensor chip has a sensing region and a carrying region that surrounds the sensing region;
an adhesive layer having an annular shape and being disposed on the carrying region of the sensor chip, wherein the adhesive layer has:
a bottom adhering surface connected to the carrying region;
a top adhering surface parallel to the bottom adhering surface, wherein an area of the top adhering surface is equal to an area of the bottom adhering surface, and the top adhering surface and the bottom adhering surface are entirely overlapped with each other along the predetermined direction; and
a middle cross section parallel to the bottom adhering surface, wherein any one of the top adhering surface and the bottom adhering surface is spaced apart from the middle cross section along the predetermined direction by a same distance, an area of the middle cross section is 90% to 110% of the area of the bottom adhering surface, and the bottom adhering surface and the middle cross section are partially overlapped with each other along the predetermined direction;
wherein the adhesive layer is configured to allow light to pass therethrough and is configured to enable the light to change a traveling direction therein and to have an attenuation therein;
a light-permeable layer having an outer surface and an inner surface that is opposite to the outer surface, wherein the light-permeable layer is disposed on the top adhering surface of the adhesive layer, so that the light-permeable layer, the adhesive layer, and the sensor chip jointly define an enclosed space; and
an encapsulant formed on the substrate, wherein the sensor chip, the adhesive layer, and the light-permeable layer are embedded in the encapsulant, and the outer surface of the light-permeable layer is at least partially exposed from the encapsulant.

9. The sensor package structure according to claim 8, wherein the adhesive layer has an inner side arranged in the enclosed space and an outer side that is connected to the encapsulant, and wherein one of the inner side and the outer side is a concave surface, and another one of the inner side and the outer side is a convex surface.

10. The sensor package structure according to claim 9, wherein, in a cross-sectional view of the adhesive layer perpendicular to the middle cross section, the convex surface has a circular arc shape having a center of circle located on the middle cross section, and the concave surface is in a circular arced shape having a center of circle that is located on a virtual plane extending from the middle cross section.

11. The sensor package structure according to claim 9, wherein, in a cross-sectional view of the adhesive layer perpendicular to the middle cross section, any one of the convex surface and the concave surface is in a circular arc shape and has a same radius.

12. The sensor package structure according to claim 8, wherein the middle cross section is perpendicular to the predetermined direction, and all cross sections of the adhesive layer perpendicular to the predetermined direction have a same area.

13. A sensor package structure, comprising:
a substrate;
a sensor chip disposed on the substrate along a predetermined direction and electrically coupled to the substrate, wherein a top surface of the sensor chip has a sensing region and a carrying region that surrounds the sensing region;
an adhesive layer having an annular shape and being disposed on the carrying region of the sensor chip, wherein the adhesive layer has:
a bottom adhering surface connected to the carrying region;
a top adhering surface parallel to the bottom adhering surface, wherein an area of the top adhering surface is equal to an area of the bottom adhering surface, and the top adhering surface and the bottom adhering surface are partially overlapped with each other along the predetermined direction; and
a middle cross section parallel to the bottom adhering surface, wherein any one of the top adhering surface and the bottom adhering surface is spaced apart from the middle cross section along the predetermined direction by a same distance;
wherein the adhesive layer is configured to allow light to pass therethrough and is configured to enable the light to change a traveling direction therein and to have an attenuation therein;
a light-permeable layer having an outer surface and an inner surface that is opposite to the outer surface, wherein the light-permeable layer is disposed on the top adhering surface of the adhesive layer, so that the light-permeable layer, the adhesive layer, and the sensor chip jointly define an enclosed space; and
an encapsulant formed on the substrate, wherein the sensor chip, the adhesive layer, and the light-permeable layer are embedded in the encapsulant, and the outer surface of the light-permeable layer is at least partially exposed from the encapsulant.

14. The sensor package structure according to claim 13, wherein an area of the middle cross section is 90% to 110% of the area of the bottom adhering surface.

15. The sensor package structure according to claim 14, wherein the adhesive layer has an inner side arranged in the enclosed space and an outer side that is connected to the encapsulant, and wherein, in a cross-sectional view of the adhesive layer perpendicular to the middle cross section, the bottom adhering surface, the top adhering surface, the inner side, and the outer side jointly form a parallelogram.

16. The sensor package structure according to claim 15, wherein, in the cross-sectional view of the adhesive layer, the parallelogram has two obtuse angles and two acute angles, and any one of the two acute angles is within a range from 10 degrees to 80 degrees.

17. The sensor package structure according to claim 13, wherein the adhesive layer has an inner side arranged in the enclosed space and an outer side that is connected to the encapsulant, and wherein one of the inner side and the outer side is a concave surface, and another one of the inner side and the outer side is a convex surface.

18. The sensor package structure according to claim 14, wherein the adhesive layer has an inner side arranged in the enclosed space and an outer side that is connected to the encapsulant, and wherein at least one of the inner side and the outer side is a curved surface, and any one of the inner side and the outer side of the adhesive layer does not have a concave surface.

19. The sensor package structure according to claim 13, wherein the adhesive layer has an inner side arranged in the enclosed space and an outer side that is connected to the encapsulant, and wherein, in a cross-sectional view of the adhesive layer perpendicular to the middle cross section, at least one of the inner side and the outer side is in a circular arc shape having a center of circle that is located in the adhesive layer and that is not located on the middle cross section.
